(19) United States
(12) Patent Application Publication
(10) Pub. No.: US 2003/0122120 A1
(43) Pub. Date: Jul. 3, 2003

(54) Organic semiconductor device and method

(75) Inventors: Paul W. Brazis JR., South Elgin, IL (US); Jie Zhang, Buffalo Grove, IL (US); Daniel R. Gamota, Palatine, IL (US); Krishna Kalyansundaram, Chicago, IL (US)

Correspondence Address: FITCH EVEN TABIN AND FLANNERY, 120 SOUTH LA SALLE STREET, SUITE 1600, CHICAGO, IL, 60603-3406, US

(73) Assignee: Motorola, Inc.

(21) Appl. No.: 10/034,645

(22) Filed: Dec. 28, 2001

(51) Int. Cl. H01L 35/24; H01L 51/00

(52) U.S. Cl. 257/40

(57) ABSTRACT

A semiconductor device comprising a flexible or rigid substrate (10) having a gate electrode (11) formed thereon with a source electrode (14) and a drain electrode (15) overlying the gate electrode (11) and organic semiconductor material (16) disposed at least partially thereover. The source electrode (14) and the drain electrode (15) each have a non-linear boundary segment that effectively extends the channel width between these two electrodes to thereby increase the current handling capability of the resultant device. In many of the embodiments, any of the above elements can be formed through contact or non-contact printing. Sizing of the resultant device can be readily scaled to suit various needs.

### TECHNICAL FIELD

This invention relates generally to semiconductors and more particularly to organic semiconductor materials.

### BACKGROUND

Components (such as field effect transistors (FETs)) and circuits comprised of semiconductor materials are known in the art. Such technology has been highly successful. For some applications, however, traditional semiconductor processing over-performs and represents unneeded form factors and capabilities at a commensurate additional cost. In addition, traditional semiconductor processing often yields small parts that present handling difficulties during assembly and further require careful packaging. Traditional semiconductor processing also usually requires batch processing to achieve a reasonable cost per part because the fabrication facilities and equipment required are extremely expensive. Also, many semiconductor devices require a lengthy fabrication time and often require numerous chemicals, some of which are highly toxic and require special handling. These aspects of traditional semiconductor fabrication do not well support low data storage and transmission applications and/or less expensive needs. An alternative is desired.

Existing semiconductor device structures meet a wide variety of needs. For example, existing semiconductor technology can be utilized to produce an FET capable of handling relatively large drain-to-source currents for use in devices and circuits such as integrated circuit power distribution, rectifier circuits, light emitting diode driver stages, audio output, and so forth. Any alternative to present semiconductor processing, to be successful, must similarly meet a significant number of these same needs including this ability to support high current applications.

### BRIEF DESCRIPTION OF THE DRAWINGS

The above needs are at least partially met through provision of the organic semiconductor device and method described in the following detailed description, particularly when studied in conjunction with the drawings, wherein:

FIGS. 1-4 illustrate a first embodiment;

FIGS. 5 and 6 illustrate yet further alternative embodiments;

FIG. 7 illustrates a cross-sectional view of the embodiment depicted in FIG. 4; and

FIGS. 8-10 illustrate alternative embodiments.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention.

### DETAILED DESCRIPTION

Generally speaking, pursuant to these various embodiments, a gate is formed on a substrate and an insulator provided to insulate the gate from further layers. A source electrode and drain electrode are then provided on the substrate above the gate dielectric. In various ways, the source electrode and drain electrode each have at least one non-linear boundary that substantially complements one another such that the non-linear boundary edges of each can be positioned relatively close to one another. Organic semiconductor material is then disposed over the source electrode and drain electrode to form an organic FET. So configured, a wide channel width results that improves current handling capability as compared to a linear channel geometry (this results because drain current is directly proportional to the channel width). The substrate can be flexible or rigid. Furthermore, any of the various elements described above can be formed through printing processes (including both contact and non-contact printing processes). As a result, extremely inexpensive high-current devices can be made without a need for batch processing, large and complicated fabrication facilities, or many of the dangerous chemicals often associated with semiconductor device processing.

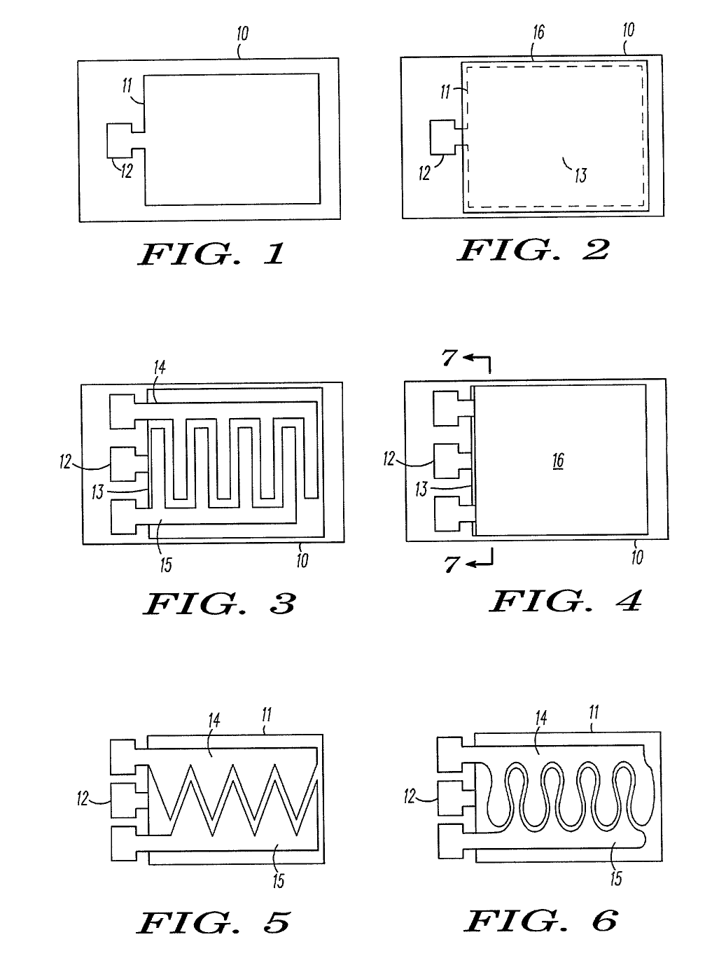

Referring now to FIG. 1, a first embodiment will be described. An initial substrate 10 can be comprised of a variety of materials, including flexible and substantially rigid materials. In general, the substrate 10 itself should be an insulator. Various plastics, including polyester and polyimide, generally work well for these purposes. Depending upon the application, however, other materials can work as well, including treated cloth and paper. The substrate 10 can be of various sizes as commensurate with the desired size of the final result.

A gate electrode 11 having a contact pad 12 is formed on the substrate 10. The gate electrode 11 comprises a conductor formed of a material such as gold, silver, copper (or other metal), conductive polymer thick films, or conductive polymers. In this embodiment, the gate electrode 11 comprises an elongate member.

Referring to FIG. 2, an insulator 13 such as a polymer is deposited over the gate electrode 11. This insulator 13 serves to insulate the gate electrode 11 from subsequent conductive layers.

Referring to FIG. 3, a source electrode 14 and drain electrode 15 are then also formed on the substrate 10 with interdigitated extensions that overlie the gate electrode 11 which is insulated by the gate insulator 13. The source electrode 14 and drain electrode 15 are formed of a conductive material. In this embodiment, both the source electrode 14 and the drain electrode 15 are seen to have a portion thereof that comprises a nonlinear boundary. The nonlinear boundaries for each electrode 14 and 15 substantially conform to one another such that the two electrodes can be positioned proximal to one another without making physical (and hence direct electrical) contact with one another. The purpose of these interdigitated extensions (formed, in this embodiment, by substantially rectangular shaped extensions) is to provide a relatively lengthy channel width as between the source electrode 14 and drain electrode 15 to thereby increase the current handling capability of the resulting device (“channel width” refers to the overall length of the channel as between the two electrodes and not the distance between the two electrodes). In general, the closer the two electrodes 14 and 15 are to one another, the better. Satisfactory results can be obtained with, for example, an average separation distance of 100 micrometers.

Referring now to FIG. 4, organic semiconductor material 16 is then applied to contact at least portions of the source electrode 14 and the drain electrode 15. The resultant device will function as an FET capable of handling relatively high current.

Any of the above elements (the electrodes 11, 14, and 15, the insulator 13, and the organic semiconductor material 16) can be formed by use of one or more relatively low-cost printing processes. For example, contact printing processes (including but not limited to stamping, screen printing, flexographic, and micro-contact printing) and non-contact printing processes (including but not limited to ink jet, electrostatic, laser transfer, and micro-dispensing) can be used to print the indicated materials as described. For the metals, nanoparticle suspensions of gold, silver, copper or other suitable materials can be used as the printing process ink. In the alternative, conductive polymer thick film material or conductive polymers can serve as the printing process ink. Depending upon the material form and carrier used, air drying and/or curing steps (as when using a thermoset polymer thick film) may be appropriate to ensure the desired adhesion and mechanical integrity.

A typical device will have an overall thickness of only a few microns (depending upon the specific materials, deposition process, and number of layers) and can have a footprint ranging from a few microns to one thousand or more microns. Notwithstanding such sizes, when formed upon a flexible substrate, the result device can maintain normal functionality even when flexed during use (of course, extreme bending of the substrate may, at some point, disrupt the continuity of one of more of the constituent elements of the device).

As an alternative approach to the embodiments just described, the substrate 10 can have an initial metallized layer, which layer can be patterned and etched to produce the gate electrode 11 depicted in FIG. 1. As stated earlier, purpose of the non-linear boundaries of the source electrode 14 and the drain electrode 15 is to effectively lengthen the channel width between these two electrodes 14 and 15 to thereby increase the current handling capability of the resultant device. This can be achieved with various geometries other than by the interdigitated rectangularly-shaped extensions disclosed above. For example, with reference to FIG. 5, a triangular pattern can be utilized (though this embodiment will likely not result in as long a channel width as the previously described embodiment). As another example, with reference to FIG. 6, the extensions can be curved rather than rectangular. Many other alternations are clearly possible. Furthermore, as shown, the extensions are all substantially identical to one another. Such symmetry has been employed for these examples for ease of presentation and explanation. In fact, however, there is no particular need or requirement for symmetry as depicted. The only requirement is that whatever non-linear boundary geometry is used for one electrode is substantially matched for at least a significant portion of the remaining electrode such that two electrodes can be positioned closely to one another and thereby yield an operative high current device.

When selecting a particular extension geometry and separation distance between the source electrode 14 and drain electrode 15, it may be appropriate to take into account the printing process or other deposition process being used as well as reception tendencies of the receiving medium. For example, ink jet application can result in consider application overlap, and such tolerances should be accounted for when selecting shapes and separation distances.

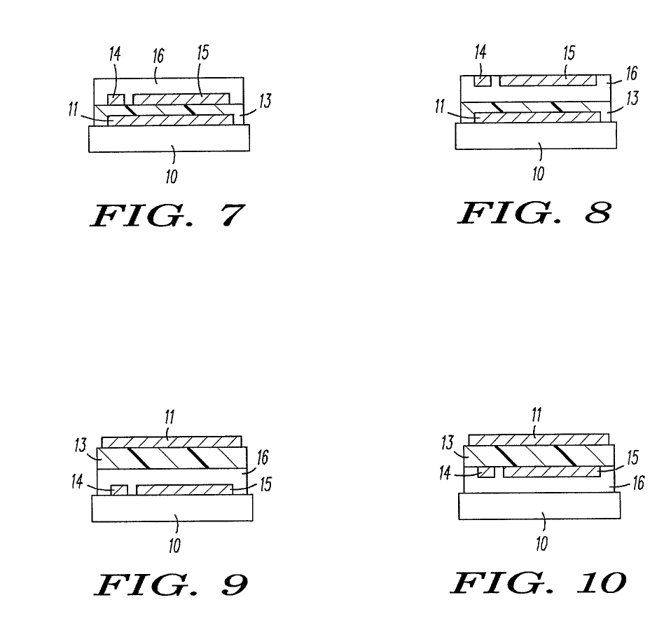

The embodiments described above present the various elements as being stacked in a particular order. As illustrated in FIG. 7 (comprising a cross-section of the embodiment depicted in FIG. 4), the semiconductor material 16 overlies the source 14 and drain 16, which overlies the dielectric 13, which overlies the gate 11, which overlies the substrate 10. Other orientations, however, are possible and acceptable. For example, with reference to FIG. 8, the source 14 and drain 15 can overlie the semiconductor material 16, which overlies the dielectric 13, which overlies the gate 11, which overlies the substrate 10 (aside from the order of presentation, these elements would otherwise be configured and deposited as described above). As another example, with reference to FIG. 9, the gate 11 can overlie the dielectric 13, which can overlie the semiconductor material 16, which can overlie the source 14 and drain 15, which can overlie the substrate 10 (again, these elements would be otherwise configured and deposited as described above). As yet another example, and with reference to FIG. 10, the gate 11 can overlie the dielectric 13, which can overlie the source 14 and drain 15, which can overlie the semiconductor material 16, which can overlie the substrate 10 (and, as before, these elements can be otherwise configured and deposited as described above). The particular orientation can be selected to suit a given application, deposition technology, and so forth as appropriate, so long as the source 14 and drain 15 remain in contact with the semiconductor material 16, the dielectric 13 insulates the gate 11 from the other elements, and the gate is at least partially coextensive with the source 14 and drain 15.

A wide variety of materials can be used consistently with the above processes and embodiments. Furthermore, a wide range of processing parameters can be varied, including device size and constituent element sizes, to suit a wide variety of application requirements. Those skilled in the art will recognize that a wide variety of modifications, alterations, and combinations can be made with respect to the above described embodiments without departing from the spirit and scope of the invention, and that such modifications, alterations, and combinations are to be viewed as being within the ambit of the inventive concept.

We claim:

1. An active device comprising:
a substrate;
a first electrode formed overlying the substrate, wherein the first electrode has at least a portion thereof comprising a nonlinear boundary;
a second electrode formed overlying the substrate, wherein the second electrode has a portion thereof comprising a nonlinear boundary that substantially conforms to at least a part of the nonlinear boundary of the first electrode and that is positioned proximal to the nonlinear boundary of the first electrode;
an organic semiconductor layer disposed in contact with at least a portion of the first and second electrode.

2. The active device of claim 1 wherein the substrate comprises a flexible substrate.

3. The active device of claim 1 wherein the substrate comprises a substantially rigid substrate.

4. The active device of claim 1 wherein the first electrode comprises a drain and the second electrode comprises a source.

5. The active device of claim 4 and further comprising a gate electrode formed overlying the substrate and being at least partially coextensive with the first and second electrode.

6. The active device of claim 5 and further comprising a dielectric layer disposed at least partially between the gate electrode and the organic semiconductor layer.

7. The active device of claim 6 wherein the dielectric layer is comprised of one of a polymer, a polymer thick film dielectric, and paper.

8. The active device of claim 1 wherein the nonlinear boundary of the first electrode comprises a plurality of extensions.

9. The active device of claim 8 wherein the plurality of extensions of the first electrode are interdigitated with a plurality of extensions of the second electrode.

10. The active device of claim 8 wherein the plurality of extensions comprise rectangular shaped extensions.

11. The active device of claim 10 wherein rectangular shaped extensions of the first electrode are interdigitated with rectangular shaped extensions of the second electrode.

12. The active device of claim 1 wherein the nonlinear boundary of the first electrode is spaced no more than 100 micrometers from the nonlinear boundary of the second electrode.

13. The active device of claim 1 wherein at least one of the first and second electrodes is comprised of at least one of a conductive metal, a conductive polymer, a conductive polymer thick film, and a conductive nano-particles filled ink.

14. A method of forming an active device comprising:
providing a substrate;
depositing a first electrode to overlie the substrate, wherein the first electrode has at least a portion thereof comprising a nonlinear boundary;
depositing a second electrode to overlie the substrate, wherein the second electrode has a portion thereof comprising a nonlinear boundary that substantially conforms to at least a part of the nonlinear boundary of the first electrode and that is positioned proximal to the nonlinear boundary of the first electrode;
depositing an organic semiconductor layer to contact at least a portion of the first and second electrode.

15. The method of claim 14 wherein providing a substrate comprises providing a flexible substrate.

16. The method of claim 14 wherein providing a substrate comprises providing a substantially rigid substrate.

17. The method of claim 14 wherein depositing a first electrode to overlie the substrate comprises printing a first electrode.

18. The method of claim 17 wherein printing a first electrode comprises contact printing a first electrode.

19. The method of claim 18 wherein contact printing a first electrode includes one of stenciling, screen-printing, flexography, stamping, and micro-contact.

20. The method of claim 17 wherein printing a first electrode comprises non-contact printing a first electrode.

21. The method of claim 20 wherein non-contact printing a first electrode includes one of ink jet printing, micro-dispensing, electrostatic printing, and laser transfer printing a first electrode.

22. The method of claim 17 wherein printing a first electrode comprises printing one of a conductive metal, a conductive polymer, a conductive polymer thick film, and a conductive nano-particles filled ink.

23. The method of claim 17 wherein printing a first electrode comprises printing a polymer thick film that includes small particles of a conductive metal.

24. The method of claim 23 and further comprising curing the polymer thick film.
